(19) United States
(12) Patent Application Publication
(10) Pub. No.: US 2023/0011380 A1
(43) Pub. Date: Jan. 12, 2023

(54) OPTICAL CHAMBER ADAPTED FOR CONTROLLING OUTPUT DIRECTION AND CONVERGENCE MODE OF LIGHT, AND OPERATIONAL SOLAR CONCENTRATOR

(71) Applicant: Wei-Yuan PAO, Taoyuan City (TW)

(72) Inventor: Wei-Yuan PAO, Taoyuan City (TW)

(21) Appl. No.: 17/839,594

(22) Filed: Jun. 14, 2022

(30) Foreign Application Priority Data
Jul. 7, 2021 (TW) 110124889

(51) Int. Cl. H02S 40/22; G02B 26/00; G02B 26/08; H02S 10/30

(52) U.S. Cl. CPC H02S 40/22; G02B 26/004; G02B 26/0816; H02S 10/30

(57) ABSTRACT

The invented optical chamber is sealed and encapsulated by a transparent element, a connection element and a transparent substrate or another transparent element. The optical chamber is filled with a transparent fluid and equipped with an electronic sensing and execution component. The surface state, the position and the inclination of the optical chamber are adjusted by the electronic sensing and execution component or through a movable part of the connection element, thereby adjusting the output direction and the focal length of the light beam. The optical chambers are combined in series or in array to constitute an operational solar concentrator adapted to output more than one controlled convergent light beam or a directional light beam to support various light energy applications, such as long-distance lighting, heating, light energy and signal transmission, increased electric energy production, and weather control. The invention is provided to adjust the internal temperature and pressure to adapt to extremely high power and extreme environments. Biotechnology is useful for obtaining the same structure and function.

### FIELD OF THE INVENTION

The invention relates to an optical chamber capable of guiding the output direction and focal length of a light beam to a designated position, and an operational solar concentrator comprising a plurality of the optical chambers which coordinate with one another to output a controllable convergent light beam according to requirements, as well as the applications thereof.

### BACKGROUND OF THE INVENTION

The conventional light collecting apparatus, such as that disclosed in R.O.C. Utility Model No. M304644, are generally configured in the form of a solar concentrator panel having a large surface area and composed of multiple concentrator plates made of glass or acrylics. Each of the solar concentrator plates corresponds to a single solar cell, so that every solar cell may efficiently receive solar energy with an enhanced energy density through the light concentrator plate corresponding thereto. However, the conventional solar concentrator panel has to be precisely oriented towards the sun, so as to transmit solar energy to the respective solar cells. To achieve this, sophisticated mechanical facilities are required to keep the large-area solar panel facing the sun and, as a result, the occurrence of mechanical failure and the problem that the sunlight is blocked by the neighboring apparatuses seem inevitable and unsolvable. Furthermore, the conventional systems are unable to control the output direction of light beams under static installation conditions and, therefore, cannot guide the light beams to the application position. Neither are they equipped with an effective mechanism for processing the photovoltaic and photo-thermal frequency bands in a separate manner to allow separate collection and utilization of solar and thermal energy with minimal engineering cost and mechanical disturbance to enhance power generation efficiency and usage flexibility.

Another light collecting apparatus is disclosed in R.O.C. Patent No. I400485, which relates to a prism array for collecting external light. The prism array includes a first light collecting prism assembly comprising a first light guide prism and at least one first reflective prism. The first light guide prism includes a first light incident surface, a first reflective surface, a first light concentrating surface, a first light transmission surface and a first light exit surface, wherein the external light entering the first light guide prism through the first light concentrating surface is reflected by the first reflective surface in a first direction and then leaves the first light guide prism via the first light exit surface. The first reflective prism is disposed adjacent to the first light exit surface, such that the first reflective prism receives the external light through the first light exit surface and reflects the external light to constitute a first light beam which is then output in a second direction. The conventional prism array is unable to guide light beams to the designated position according to the user's demand. Neither is it equipped with an effective mechanism for processing the photovoltaic and photo-thermal frequency bands in a separate manner to allow separate collection and utilization of solar and thermal energy with minimal engineering cost and mechanical disturbance to enhance power generation efficiency and usage flexibility.

Some conventional controllable optical elements, such as the liquid lenses disclosed in Taiwan Patent Nos. I336788, I437272 and I467815, employ the electro-wetting technology and the curvature and shape of the contact area and the liquid interface of the liquid lenses are controlled by adjusting the voltage difference between the electrodes coated with insulating layers to change the focal length. However, the insulating layer-coated electrodes in these conventional devices are not provided in plurality or divided into sections, such as arranged or divided into arrays, layers, radial arrangement. Therefore, they are not adapted for or capable of adjusting the inclined degree and inclined direction of the liquid interface by controlling the contact area asymmetrically. Even if these conventional devices are arranged into an array, there is no teachings provided in the art to have them work cooperatively to converge light beams according to specific demands.

### SUMMARY OF THE INVENTION

In response to the above-mentioned problems in the art, an optical chamber adapted to guide an output direction of a light beam to a designated application position, as well as an operational solar concentrator comprising a number of the optical chambers, are provided herein.

In order to achieve the above object, the optical chamber according to the invention comprises: a transparent substrate having a first surface and a second surface opposite to the first surface; a transparent element having a third surface, a fourth surface opposite to the third surface and an edge; at least one connection element coupled between the transparent element and the transparent substrate, or between the transparent elements, or between the transparent substrates; the connection element being a movable part and/or a bracket, so that objects connected thereto are either elevated to a fixed position, or arranged to be movable and swingable; the optical chamber being sealed and encapsulated by the transparent substrate, the transparent element and the connection element, or by the two transparent elements and the connection element; the optical chamber is configured in a spherical, a polyhedral or an elongated shape, with its interior filled with one or more transparent fluids.

The movable part may include but be not limited to an elastic soft film structure, a flexible soft film structure, a telescopic part, a rotary part, a bearing, a slidable part, an electroactive polymer and a combination thereof, which allows the optical chamber to move telescopically, rotationally, swingingly or slidingly along a predetermined direction and allows the optical chamber and especially the transparent element to change their swing direction or curvature; the elastic soft film structure or the flexible soft film structure being provided with an auxiliary motion reservation structure or mounted on the bracket; the auxiliary motion reservation structure being formed by bending or folding the elastic soft film structure or the flexible soft film structure to have a predetermined height, length and motion space; the telescopic part being selected from the group consisting of a balloon telescopic cell, a folded telescopic cell, and other pneumatic, hydraulic, electrical, mechanical, piezoelectric telescopic parts, and electroactive polymers.

In one preferred embodiment, at least one unsealed zone is formed between the connection element and the second surface, between the connection element and the third surface, on the bracket, or between the bracket and the movable part, wherein the unsealed zone is a normally open channel, a normally closed gap or an external port for communicating the optical chambers with one another or with outside when necessary.

The transparent element may be an elastic soft film structure or a flexible soft film structure with high ductility, or an electroactive polymer, or a thin plate structure, which is mounted to, or coated on, or adhered to the connection element. The thin plate structure may be a planar thin plate, a thin plate or a lens with a curved surface, or a Fresnel lens with a serrated curved microstructure.

An electronic sensing and execution component is mounted within or on the optical chamber or installed on another structure. Alternatively, said component may be disposed on the first surface or the second surface of the transparent substrate and on the fourth surface or the third surface of the transparent element, or disposed on an inner side or an outer side of the connection element or embedded or sandwiched therein, or disposed in the unsealed zone, such as in a normally open channel or a normally closed gap or an external port. Preferably, said component is transparent, miniaturized or nearly transparent and is fabricated by coating circuits and devices on the surfaces using multi-layer printing or transfer-printing technology or patterned film technology. The electronic sensing and execution component includes, but is not limited, to one or more capacitive electrodes, inductive coils, resistors, photosensitive devices and signal loading devices and a combination thereof, arranged in staggered, arrayed, (multi-segmented) annularly disposed, radially disposed, arbitrarily disposed or other manner. By inducing an electric field or generating an electromagnetic force, the capacitive electrodes and the inductive coils act to adjust the swing direction and the curved contour of the transparent element, or the curvature and the inclined attitude of liquid level, or a certain complex detail, or further participate in signal loading processing, or switch the unsealed zone from open to closed or vise versa, or further detect the swing direction and curved state of the transparent element. The resistors serve to supply heat to prevent fogging or maintain the temperature to keep the liquid in liquid state. The photosensitive devices, when being arranged in a planar array, are capable of detecting the coordinates and direction of a light beam passing through. The array of the photosensitive devices may be arranged to detect light incident from the same direction or divided into several groups for detecting light incident from different directions. The signal loading device may comprise, but be not limited to, a liquid crystal module, a plasma module, a piezoelectric module, a polarization module, an electroactive polymer, and other devices capable of controlling an optical property.

A number of the optical chambers are combined in series or in an array to constitute the operational solar concentrator. The transparent substrates or the transparent elements are arranged in a single layer or in multiple layers, and the connection elements are coupled between the transparent substrates or the transparent elements of the respective layers to either fix and connect them with each other or allow them to be movable and swingable, so that the optical chambers of a same layer and respective layers are arranged according to a predetermined position, amount, size, inclined degree and spacing, or adapted for further movement, adjustment and deformation. The arrangement may vary and include, but be not limited to, a certain layer of the transparent substrates being of a simple planar structure, a certain layer of the transparent substrates being of a multi-faceted three-dimensional structure or a multi-faceted three-dimensional array, a certain layer of the transparent substrates being divided into a plurality of independent movable sections, a certain layer of the transparent substrates being adapted for moving freely and independently, the outermost transparent substrates serving as upper and lower packaging transparent substrates and constituting a weatherproof package structure to protect the optical chambers disposed therewithin.

The external port is provided with or without a removable high and low pressure external conduit adapted for entry and exit of a liquid into and out of the optical chamber or the intermediate spaces defined by the upper and lower packaging transparent substrates for purposes of temperature and pressure regulation, liquid circulation and substitution.

In one preferred embodiment, at least one high- or low-pressure pipeline may be disposed inside the bracket or serves as a part of the bracket, or disposed on the connection element, so as to perform a fast and low-interference circulation.

In one preferred embodiment, the high and low pressure conduit is provided with at least one micro-hole, micro-tube or valve-equipped flat tube, which is directed to the optical chamber or the telescopic part to assist in regulating pressure and telescopic state.

In one preferred embodiment, a flow control valve is disposed in the high and low pressure conduit, the micro-hole or the micro-tube, and the flow control valve includes but is not limited to a valve-equipped flat tube, a valve plug, an electromagnetic mechanical flow control valve and an electroactive polymer.

In one preferred embodiment, the valve-equipped flat tube or the valve plug is further provided with or without a capacitive electrode or an inductive coil, so that the valve-equipped flat tube or the valve plug becomes a controllable flow control valve like an electromagnetic mechanical flow control valve to perform on and off states by inducing an electric field or a magnetic field.

In one preferred embodiment, the first surface or the fourth surface of the optical chamber is coated with an optical film to become a special optical device. The optical film includes but is not limited to a filter film, a semi-transparent film, a reflective film and a multi-energy level film. Alternatively, the special optical device adopts a conventional reflector or other optical device which includes but is not limited to a planar mirror, a concave mirror and a convex mirror.

The operational solar concentrator is adapted to, according to a command, change orientations of light beams output from the respective optical chambers among multiple application positions by using various items and devices in a wide application space, so as to generate one or more converged light beams, and adapted to adjust an amount of the converged light beams and an intensity of converged light energy. When the converged light beam is re-concentrated into a directional light beam, the application distance of the light beam is greatly increased. When the system is equipped with a camera and a computer vision technical module or connected with a data link, the converged light beam or the directional light beam is adapted for tracking and directing the light beam towards a moveable target.

The operational solar concentrator is applicable in the solar energy industry and is adapted for separating light energy and thermal energy to focus them on different positions at low cost, so that a photovoltaic power generation device and a photothermal power generation device can generate electricity at the same time without interference. The two power generation devices can operate at the same time, with each maintaining its highest power generation efficiency. The extensive use of photothermal power generation further improves the power conversion efficiency and reduces the area occupied by photovoltaic power generation. The invention also eliminates the risk of mechanical failure by not relying on a sun tracking system.

The operational solar concentrator is applicable in cutting large objects, such as cutting rocks, buildings, tunnels and underground spaces, transforming terrain, or heating cheap materials such as heating sand and gravel into molten lava, pouring into formwork and then cooling it to realize casting, and construction. The operational solar concentrator also supports directional beam communication, light beam probing and light beam energy transmission. When the operational solar concentrator is provided with a reflective film, the converged light beam or the directional light beam can be projected at a wider range to support various aerospace activities.

In one preferred embodiment, the entire mechanical architecture and system of the operational solar concentrator are realized by a bio-architecture and system, which involves application of biotechnology, genetic engineering and cell technology, with reference to the architecture of the operational solar concentrator and the operation mechanism of chameleon epidermal cells, thereby producing the operational solar concentrator comprising artificial cell and tissue planar arrays, which are attached on the transparent substrate or within a weatherproof package, and wherein small channels and apertures are formed, through which a nutrient solution or a culture medium may be transmitted.

In one preferred embodiment, artificial optical chamber cells or eyeball crystal-like and ciliary muscle-like structures are arranged on the artificial cell and tissue planar arrays and controlled by electrodes, electronic signal wiring or nerve cells so that the respective optical chamber cells or the respective eyeball crystals can be deformed in a controlled manner and enabled to output light individually or converging a light beam cooperatively.

In one preferred embodiment, it can be further realized by vascular bundle cells or blood circulation system disposed for mass transfer and temperature control; photosynthetic cells or pigment cells are disposed on the outermost layer or disposed in proportion to the optical chamber cells to provide operational energy source so that the light-receiving areas and deformation degrees of the respective cells, as well as the light transmittance or the output direction of the reflected light, are adapted for controlled adjustment; other sustentacular cells and tissues include but are not limited to: epidermal tissues adapted to prevent foreign substances from entering the system and prevent water from evapotranspiration; stem cells or proliferative tissues responsible for repair and controlled growth, allowing automatic repair and growth under controlled conditions to scale up the system and even facilitating synthesis of the transparent substrate through biological metabolism during proliferation of cells, and the operation of known blood cells.

The optical chamber adapted for controlling an output direction of a light beam, or an operational solar concentrator comprising a plurality of the optical chambers, or a weatherproof packaging structure comprising the optical chambers, which is installed by the following modes: directly mounted on, replacing, or constitutes a roof, or mounted on a relatively high static position, or installed in form of a polyhedral three-dimensional structure, or mounted on a mobile device or a mobile bracket, or mounted on an aerostat platform or an aerostat vehicle. The mobile device or the mobile bracket may include, but be not limited to, a bracket, a light source vector sensor and a movable part, so that the dynamic platform can move to track the sun or increase the output range. The aerostat platform or the aerostat vehicle may be a hot air aerostat platform, such as hot air balloon and a helium vehicle, a mechanical aerostat platform, such as a Dyson sphere and a space elevator, an orbital aerostat platform, such as a satellite and a space station, or a powered aerostat platform, such as a drone.

In one preferred embodiment, the invention is further provided with a plurality of light pipes which comprise light receiving ends arranged in intensive array at the output side of at least one optical chamber and terminal ends arranged in communication with the output directions or the light-shielded spaces where light cannot arrive. The light beams output from the respective optical chambers or from a mirror assembly of the optical chambers connected in series can be directed to the light pipes. The light receiving end and the terminal ends are either secured at fixed positions or moveable by being mounted on a mobile member or a movable bracket.

In one preferred embodiment, the terminal ends of the light pipes are provided with a special optical device, such as an adjustable reflective mirror, an optical diffuser or a light scatterer, as a means to adjust the output at the terminal ends.

### BRIEF DESCRIPTION OF THE DRAWINGS

FIG. 1 is a schematic structural diagram of an optical chamber according to the first embodiment of the invention;

FIG. 2 is a schematic diagram showing the optical chamber according to the first embodiment of the invention during use;

FIG. 3 is a schematic structural diagram of an optical chamber according to the second embodiment of the invention;

FIG. 4 is a schematic structural diagram of an optical chamber according to the third embodiment of the invention;

FIG. 5 is a schematic structural diagram of an optical chamber according to the fourth embodiment of the invention;

FIG. 6 is a schematic structural diagram of an optical chamber according to the fifth embodiment of the invention;

FIG. 7 is a schematic structural diagram of an optical chamber according to the sixth embodiment of the invention;

FIG. 8 is a schematic structural diagram of an optical chamber according to the seventh embodiment of the invention;

FIG. 9 is a schematic structural diagram of an optical chamber according to the eighth embodiment of the invention;

FIG. 10 is a schematic diagram showing the position of an electronic sensing and execution component in the invention;

FIG. 11 is a schematic structural diagram of an optical chamber according to the ninth embodiment of the invention;

FIG. 12 is a schematic structural diagram of an optical chamber according to the tenth embodiment of the invention;

FIGS. 13A to 13D are schematic structural diagrams of optical chambers according to the eleventh to fourteenth embodiments of the invention; and

FIGS. 14A to 14B are schematic structural diagrams of optical chambers according to the fifteenth to sixteenth embodiments of the invention.

### DETAILED DESCRIPTION OF THE PREFERRED EMBODIMENTS

In order to facilitate the examiner's understanding of the technical features, contents and advantages of the invention, as well as the effects achieved thereby, the invention will be described in detail hereafter in the form of embodiments and with reference to the accompanying drawings. The drawings herein are provided merely for illustrative purposes and may not necessarily indicate the actual sizes and the precise arrangements of the constituting elements during the implementation of the invention. Therefore, the sizes and structural arrangements depicted in the accompanying drawings not be interpreted as limitation to the scope of the invention as defined in the claims.

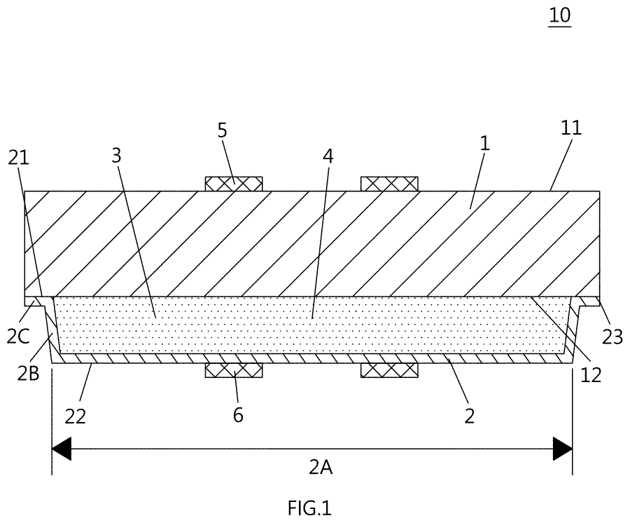

Referring to FIG. 1 which is a schematic structural diagram of the optical chamber according to the first embodiment of the invention. The optical chamber 3 according to the invention comprises the following constituting elements.

A transparent substrate 1 has a first surface 11 and a second surface 12 opposite to the first surface.

A transparent element 2 has a third surface 21, a fourth surface 22 opposite to the third surface 21, and an edge 23.

A connection element 2B is coupled between the transparent substrate 1 and the transparent element 2, or between two transparent substrates 1, or between two transparent elements 2, so as to secure the objects and establish a connection between them. The connection means applied at the joint 2C may include heating, adhesive bonding, ultrasonic pressurizing and fastening.

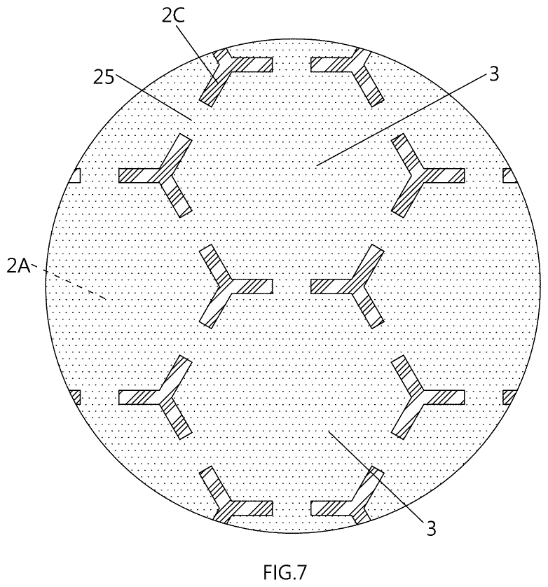

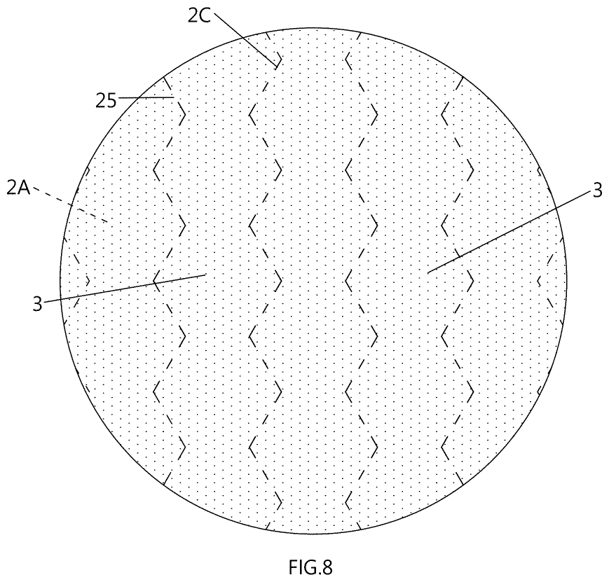

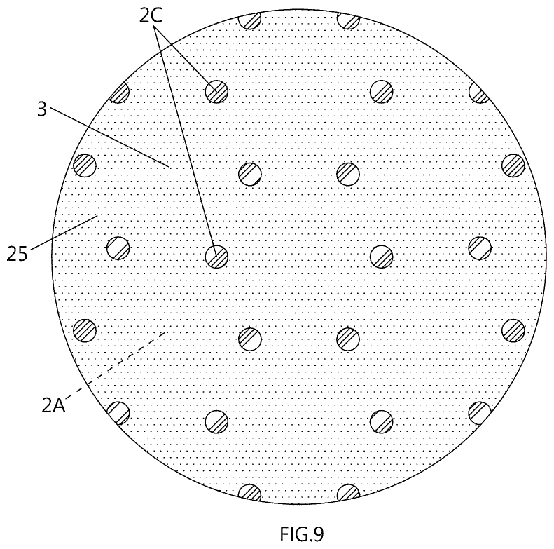

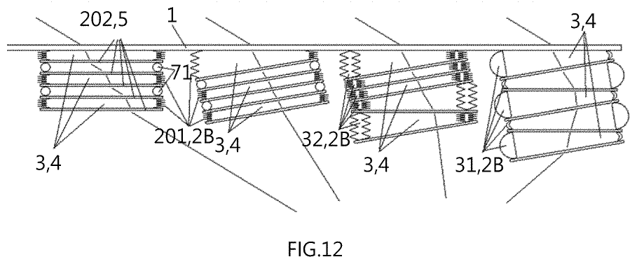

The optical chamber 3 may comprise a space delineated by the second surface 12, the transparent element 2 and the connection element 2B. Alternatively, the optical chamber 3 may comprise a space delineated by a plurality of the transparent elements 2 and a plurality of the connection element 2B, as shown in FIG. 12. The optical chamber 3 is filled with a transparent fluid 4. As further shown in FIGS. 7, 8, 9, and 10, the optical chamber 3 may be configured in various shapes, including but being not limited to a spherical, a polyhedral and an elongated shape. At least one unsealed zone 25 is provided at the joint 2C between the adjacent optical chambers 3 mounted on a same layer, allowing the optical chambers 3 to communicate with each other, with the respective joints 2C being configured in form of a strip-like or a dot-like structure.

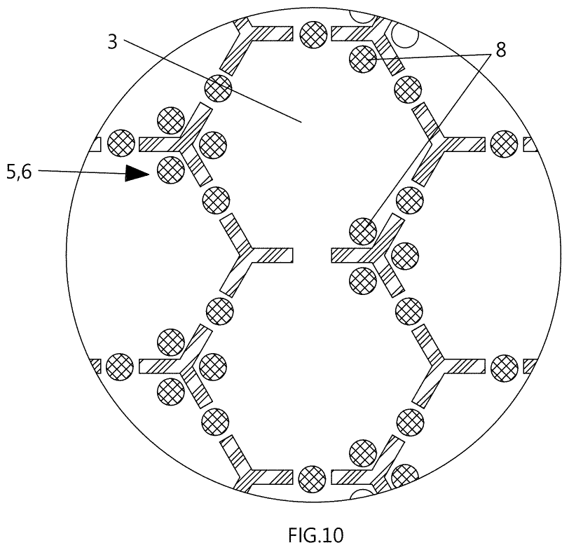

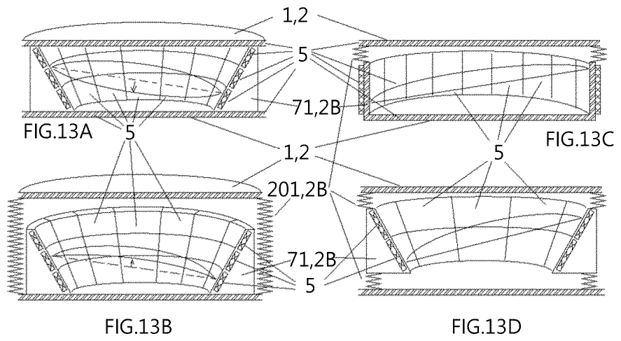

The electronic sensing and execution component 5 may be mounted on the first surface 11, the second surface 12, the third surface 21 or the fourth surface 22. Alternatively, the electronic sensing and execution component 5 may be disposed in the unsealed zone 25, as shown in FIG. 10. The unsealed zone 25 may be configured in form of a normally open channel, a normally closed gap or an external port. Still alternatively, the electronic sensing and execution component 5 may be mounted on the connection element 2B or a bracket 71, as shown in FIG. 13. In the case where more than two types of fluids are filled, a conductive fluid is brought in contact with a bare electrode, and an electrode coated with an insulating layer is disposed near an interface of the conductive fluid and a non-conductive fluid, so that the contact area between the conductive fluid and the electrode with the insulating layer may be changed by adjusting the voltage difference (electro-wetting effect). The insulating layer is usually treated to repel the conductive fluid. In the case where a plurality of insulating layer-coated electrodes are provided at various spots, such as arranged in an array or in a radially symmetrical layout, each insulating layer-coated electrode could use under different voltage to have different contact area, whereby the curvature and inclination direction of the liquid level, and even a more complicated liquid level and optical state, can be controlled and fine-tuned through the electro-wetting technology.

The electronic sensing and execution component 5 may comprise a nearly transparent, multi-layered and extremely thin or extremely narrow circuit, which may be either fabricated by a printing/transfer-printing or a coating process, or additionally mounted. The electronic sensing and execution component 5 includes but is not limited to a capacitive electrode, an inductive coil, a resistor, an array of photosensitive devices, a signal loading device and an electroactive polymer.

By inducing an electric field or generating an electromagnetic force, the capacitive electrode and the inductive coil may act to adjust the swing direction or the curved contour of the transparent element 2 or the transparent fluid 4, or facilitate the responsive motion of the transparent element 2, the optical chamber 3 or the transparent fluid 4 which is provided with an electroactive polymer, or further participate in telecommunication signal loading processing, or switch the unsealed zone from open to closed or vise versa, or further detect the swing direction and the curved state of the transparent element.

The resistor serves to supply heat to prevent fogging or maintain the temperature to keep the liquid in liquid state.

The photosensitive devices, when being arranged in a planar array, are adapted to detect the coordinates of a light beam passing through, or receive a telecommunication signal loaded in a source light beam.

The array of the photosensitive devices may be arranged to detect light incident from the same direction. Alternatively, they may be divided into several groups (i.e., at least three groups) for detecting light incident from different directions. That is to say, the at least three groups of photosensitive devices are disposed around the array and arranged to face at least three different directions. Alternatively, the array is divided into multiple small areas, each including three photosensitive devices facing towards different directions. The incident direction of a light source or the output direction of a light beam may be calculated according to the power differences of the photosensitive devices facing towards different directions.

The signal loading device is adapted to upload signals to a light beam by changing the optical property of a light source, such as by changing the intensity, the phase, the frequency, the polarization degree, the projected position or the focal position. The signal loading device may include but be not limited to a liquid crystal module, a piezoelectric module and a polarization module.

The electroactive polymer may be coated as a thin layer on the transparent element 2. Alternatively, the optical chamber 3 itself is made of the electroactive polymer. The optical chamber 3 may undergo a shape change in response to a change in the electric field, whereby the output direction and the convergence of the output light beam may be controlled. The electroactive polymer may also participate in signal loading processing.

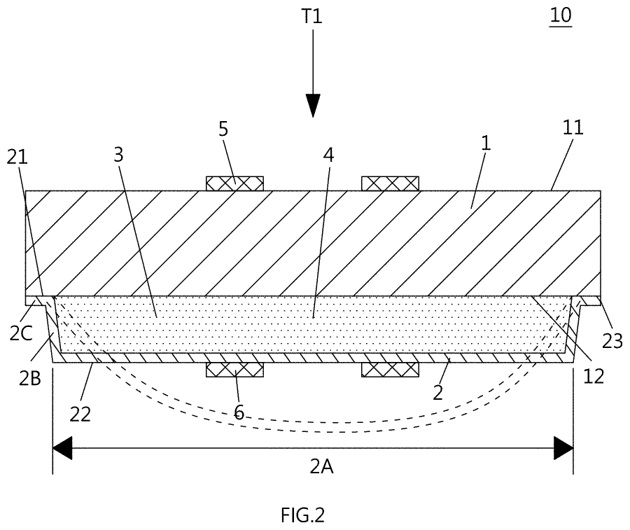

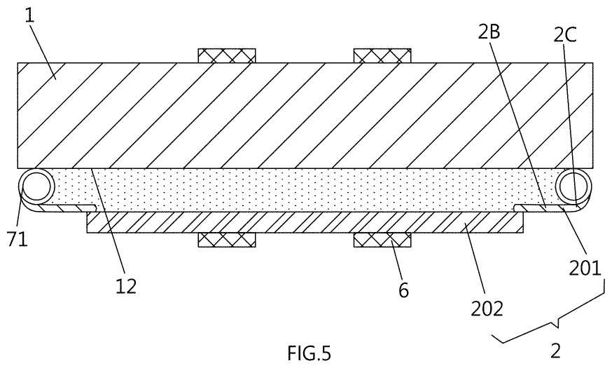

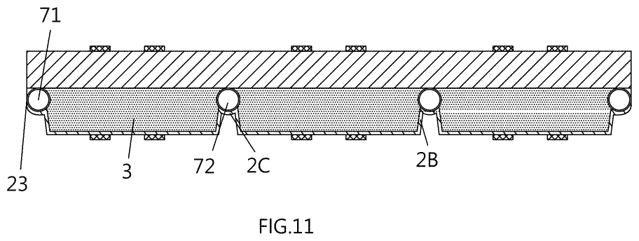

Referring to FIGS. 2, 3, 4, 5, 6, 11, 12, and 13, the connection element 2B may be configured as a movable part or the bracket 71. The movable part may comprise but be not limited to an elastic soft film structure 201 or a flexible soft film structure 201 and may be provided with an auxiliary motion reservation structure, which has a predetermined height or length with high telescopic elasticity like a balloon or is foldable and telescopic. The movable part may further comprise but be not limited to a telescopic part, a rotary part, a bearing, a slidable part and an electroactive polymer. The telescopic part may comprise but be not limited to a balloon telescopic cell 31, a folded telescopic cell 32, and other pneumatic, hydraulic, electrical, mechanical, piezoelectric telescopic devices and electroactive polymers. The transparent element 2 or the optical chamber 3 may be oscillated, moved or deformed by using the movable part.

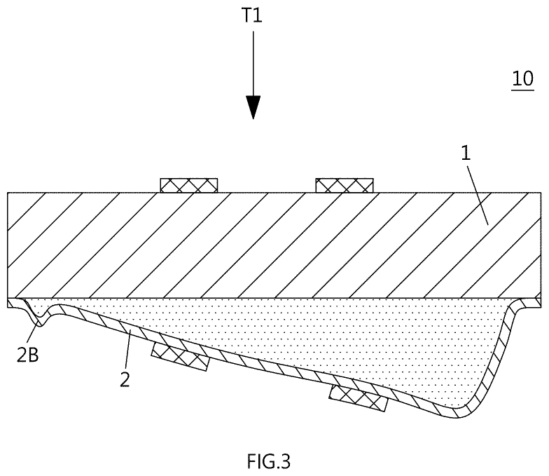

As shown in FIG. 2 and FIG. 3, a light beam enters the optical chamber 3 along a reference direction T1 at an included angle equal to or less than 90 degrees, and is output from the fourth surface 22 of the transparent element 2.

When it is desired to change the light beam output path, the electronic sensing and execution component 5 or the movable part serves to force the transparent element 2 or the transparent fluid 4 to undergo a change in swing direction, swing angle or surface curvature. The inclined angle or the position of the optical chamber 3 or the transparent fluid 4 can also be adjusted, such that the output light beam of the optical chamber 3 can be modified. As a result, the output direction and the focal point of the output light beam can be directed to any designated position.

The transparent element 2 may be configured in form of an elastic soft film structure 201 or a flexible soft film structure 201 with high ductility, or an electroactive polymer, so that the it can undergo a bending or stretching deformation under the action of an external force. The transparent element 2 may be configured such that it is adapted to be deformed from a normally planar configuration to a concave, a convex or an inclined configuration and when an applied force disappears, the transparent element 2 can restore the planar state due to its elastic nature or with the assistance of an additional force.

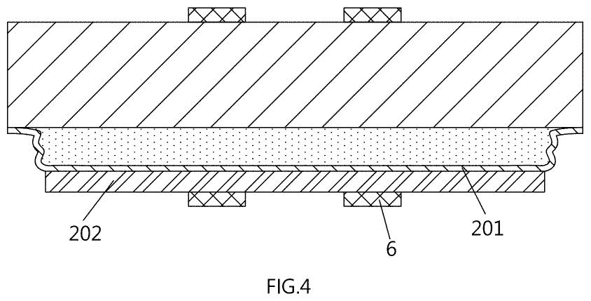

As shown in FIGS. 4, 5, 12, 13 and 14, the transparent element 2 may be of a thin plate structure, which may be a planar thin plate, a thin plate or a lens with a curved surface, or a Fresnel lens with a serrated curved microstructure, and may be connected to, or covered on, or adhered to the connection element 2B.

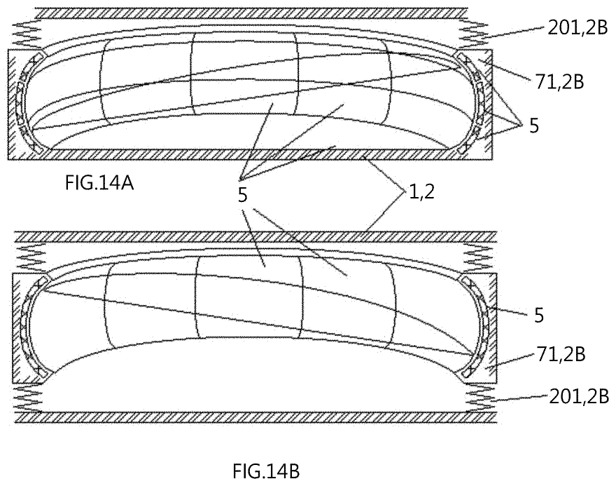

As shown in FIG. 13 and FIG. 14, in the case where more than two types of fluids are filled in the interior and form a liquid level in the interior, a conductive fluid is brought in contact with a bare electrode, and an electrode coated with an insulating layer is disposed near an interface of the conductive fluid and a non-conductive fluid, so that the contact area between the conductive fluid and the electrode with the insulating layer can be changed by adjusting the voltage difference (electro-wetting effect). The insulating layer is usually treated to repel the conductive fluid. In the case where a plurality of insulating layer-coated electrodes are provided at various spots, such as arranged in an array or in a radially symmetrical layout, the contact area may vary from one insulating layer-coated electrode to another by varying the voltage differences between the respective insulating layer-coated electrodes and the bare electrode, whereby the inclination of the liquid level, and even a more complicated liquid level and optical state, can be controlled and fine-tuned through the electro-wetting technology.

When a temperature and pressure control is required in the embodiments described above, at least one external port may be further provided in the unsealed zone 25 or on the bracket 71 toward its outer surface. The external port is provided with a removable high- or low-pressure external conduit or a removable sealing cap. The external conduit is adapted for entry and exit of a liquid into and out of the optical chamber 3 for the purposes of temperature-controlled circulation or pressure control.

In one preferred embodiment, at least one pipeline, or at least one high- or low-pressure pipeline is disposed inside the bracket 71 or serves as a part of the bracket 71, or disposed on the connection element 2B. The at least one pipeline is either directly connected to the external conduit, or indirectly connected to the external conduit through the external port, so as to perform a fast and low-interference circulation.

In one preferred embodiment, the high- or low-pressure pipeline is provided with at least one micro-hole, micro-tube or valve-equipped flat tube to assist the optical chamber 3 or the telescopic part in regulating the pressure or the telescopic state.

In one preferred embodiment, the high- or low-pressure pipeline, the micro-hole or the micro-tube may be provided with or without a flow control valve which includes but is not limited to a valve-equipped flat tube, a valve plug, an electromagnetic mechanical flow control valve and an electroactive polymer. The valve-equipped flat tube or the valve plug may be further provided with a capacitive electrode or an inductive coil, so that the valve-equipped flat tube or the valve plug is converted to an operational flow control valve like an electromagnetic mechanical flow control valve or an electroactive polymer.

In one preferred embodiment, the first surface 12 or the fourth surface 22 of the optical chamber 3 may be coated with an optical film to become a special optical device. The optical film may include but be not limited to a filter film, a semi-transparent film, a reflective film, and a multi-energy level film. Alternatively, the special optical device may adopt a conventional reflector or other optical device which includes but is not limited to a planar mirror, a concave mirror and a convex mirror.

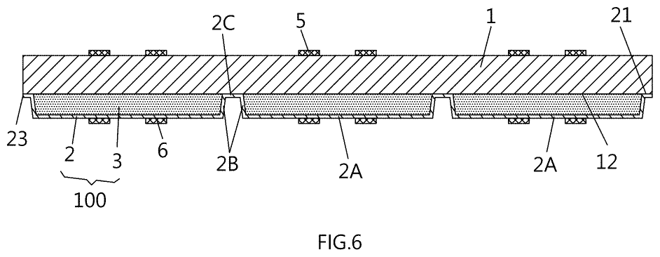

As shown in FIGS. 6, 7, 8, 9, 10, 11 and 12, a number of the optical chambers disclosed herein may be combined in series or in an array to constitute an operational solar concentrator. The transparent substrates 1 or the transparent elements 2 may be arranged in a single layer or in multiple layers, and the connection elements 2B are coupled between the transparent substrates 1 or the transparent elements 2 of the respective layers to either fix and connect them with each other or allow them to be movable and swingable, so that the optical chambers 3 of a same layer and respective layers are arranged according to a predetermined position, amount, size, inclined degree and spacing, or adapted for further movement, adjustment and deformation. The aforesaid arrangement may vary and include, but be not limited to, a certain layer of the transparent substrate 1(s) being of a simple planar structure, a certain layer of the transparent substrate(s) 1 being of a multi-faceted three-dimensional structure or a multi-faceted three-dimensional array (not shown), a certain layer of the transparent substrates 1 being divided into a plurality of independent movable sections (not shown), and a certain layer of the transparent substrate(s) 1 being adapted for moving freely and independently (not shown). The outermost transparent substrates 1 may serve as upper and lower packaging transparent substrates (not shown) and constitute a weatherproof package structure to protect the optical chamber(s) disposed therewithin.

As shown in FIG. 10, the electronic sensing and execution component 5 may comprise at least three devices evenly distributed with respect to the optical chamber 3. The size, shape, location and amount of the electronic sensing and execution component 5 are not limited to those shown in FIG. 10. The electronic sensing and execution component 5 may be of other shapes and arrangements, such as, among others, an array arrangement, an annular arrangement and a full arrangement. The positions, sizes, shapes and quantity of the electronic sensing and execution components 5 in the respective layers are not necessarily the same. A detailed structure thereof may comprise a patterned layer, an insulating layer and a wiring layer stacked in sequence, and these layers may be stacked repeatedly according to needs and complexity of the circuitry. The electronic sensing and execution components 5 are connected to each other by the wiring layer. Alternatively, they are directed to lead joints (not shown) provided on a periphery of a lens and connected to an external driver circuit (not shown) through external leads (not shown).

In one preferred embodiment, the transparent fluid 4 or the transparent element 2 may contain a special molecule, which is an electroactive polymer adapted to be induced by an electromagnetic field to undergo a conformational change or a stress change, thereby accelerating and increasing the deformation of the transparent fluid 4 or the transparent element 2. By virtue of the arrayed distribution or annular arrangement of the capacitive electrodes or inductive coils of the electronic sensing and execution component 5, individual electromagnetic fields may be applied to the respective coordinates on the transparent element 2 to control the stress level and the curve direction at each coordinates, thereby achieving finer and variable control of the curved surface of the transparent element 2.

In one preferred embodiment, the capacitive electrodes or inductive coils are arranged to detect the distance between the electrode plates or between the inductive coils by measuring the changes in oscillation frequency of a oscillating circuit, such as an RC and an LC, or the phase of a small signal voltage or current, and from there the thickness and the angular direction at each coordinates of the transparent element 2 and the optical chamber 3 can be calculated.

In one preferred embodiment, the capacitive electrodes or inductive coils may be used as a means for signal loading of a light beam by transmitting small signals to adjust the light beam output direction or the vibration at the focal position or alter the standing wave characteristics of the optical chamber 3.

According to the invention, the optical chamber 3 is used to directly enclose a liquid in a controlled system. In the case where there is no gas-to-liquid boundary or liquid-to-liquid boundary, the invention is highly stable and can withstand special conditions, such as optical chamber inclination, vibration, severe acceleration and deceleration, and allows easy correction of the pressure level and the liquid amount in the optical chamber under any abnormal conditions to prevent the occurrence of any form of liquid misplacement, such as evaporation, condensation or sticking on inner surfaces, without the occurrence of miscibility and emulsification between multiple fluids. When more than two types of fluids are used, a conductive fluid contacts a bare electrode, and an electrode with an insulating layer is disposed near an interface with a non-conductive fluid, a contact area between the conductive fluid and the electrode with the insulating layer is changed by a voltage difference (electro infiltration effect), and the insulating layer is usually treated hydrophobically for the conductive fluid. When the electrode with the insulating layer has a plurality of areas, such as arranged in an array or radially symmetrical partitions, different contact areas can be generated by different voltages respectively to be capable of controlling and correcting liquid level inclination, or generating more complex liquid level and optical conditions, which is an electro infiltration technology capable of controlling liquid level inclined direction. In the case where more than two types of fluids are used, a conductive fluid is brought in contact with a bare electrode, and an electrode coated with an insulating layer is disposed near an interface of the conductive fluid and a non-conductive fluid, so that the contact area between the conductive fluid and the electrode with the insulating layer can be changed by adjusting the voltage difference (electro-wetting effect). The insulating layer is usually treated to repel the conductive fluid. In the case where a plurality of insulating layer-coated electrodes are provided at various spots, such as arranged in an array or in a radially symmetrical layout, the contact area may vary from one insulating layer-coated electrode to another by varying the voltage differences between the respective insulating layer-coated electrodes and the bare electrode, whereby the inclination of the liquid level, and even a more complicated liquid level and optical state, can be controlled and fine-tuned through the electro-wetting technology.

In one preferred embodiment, the invention is provided with a special optical device. For example, the optical chamber 3 may be coated with various optical films. The optical film may include but be not limited to a filter film, a semi-transparent film, a reflective film, and a multi-energy level film. Alternatively, the special optical device may adopt a conventional reflector or other optical device which includes but is not limited to a planar mirror, a concave mirror and a convex mirror. The special optical device enables transmission of a convergent light beam or a directional light beam to a larger range and adjustment of the focal length or convergence of the transmitted light beam.

According to a preferred embodiment of the operational solar concentrator, an array of the planar optical chambers 3 can serve to converge more than one convergent light beam at its output side. The converged light beam is then transmitted to either a concave optical chamber 3, or a convex reflective film or reflector, so that the converged light beam is re-concentrated into a directional light beam to greatly improve its transmission distance. Of course, the key components responsible for the re-concentrated output may be equipped with a movable part, such as a slidable part for changing coordinates, and a bearing, a rotary part and telescopic part for adjusting inclination degree, so that these key components are able to move freely and change angles.

When the system is equipped with a camera and a computer vision technical module or connected with a data link, the converged light beam or the directional light beam is adapted for tracking and directing the light beam towards a moveable target and can be applied in cutting large objects, such as cutting rocks, buildings, tunnels and underground spaces, transforming terrain, or heating cheap materials such as heating sand and gravel into molten lava, pouring into formwork and then cooling it to realize casting, three-dimensional printing, construction, building repair and reinforcement. The invention may also support directional beam communication, light beam probing and light beam energy transmission. When the invention is provided with a reflective film, the converged light beam or the directional light beam can be projected at a wider range to support various aerospace activities.

In one preferred embodiment, the entire mechanical system of the operational solar concentrator is realized by a bio-system, which involves application of biotechnology, genetic engineering and cell technology, with reference to the architecture of the operational solar concentrator disclosed herein and the operation mechanism of chameleon epidermal cells. The operational solar concentrator comprising artificial cell and tissue planar arrays can be produced accordingly. The artificial cell and tissue planar arrays may be attached on the transparent substrate 1 or within a weatherproof package. The transparent substrate 1 may be formed with apertures, through which a nutrient solution or a culture medium may pass.

In one preferred embodiment, at least the optical chamber cells or eyeball crystal-like and ciliary muscle-like structures are arranged on the artificial cell and tissue planar array and controlled by electrodes, electronic signal wiring or nerve cells so that the respective optical chamber cells or the respective eyeball crystals can be deformed in a controlled manner and enabled to output light individually or converging a light beam cooperatively.

Additional supportive embodiments include vascular bundle cells or blood circulation system for mass transport and temperature control; photosynthetic cells or pigment cells disposed on the outermost layer or disposed in proportion to the optical chamber cells to provide operational energy source so that the light-receiving areas and deformation degrees of the respective cells, as well as the light transmittance or the output direction of the reflected light can be adjusted in a controlled manner; epidermal tissues adapted to prevent foreign substances from entering the system and prevent water from evapotranspiration; stem cells or proliferative tissues responsible for repair and controlled growth, allowing automatic repair and growth under controlled conditions to scale up the system and even facilitating synthesis of the transparent substrate through biological metabolism during proliferation of cells.

The optical chamber adapted for controlling the output direction of a light beam as disclosed herein, as well as the operational solar concentrator or the weatherproof packaging structure comprising the optical chamber, may be installed by the following modes: directly mounted on, replacing, or constitutes a roof, or mounted on a relatively high static position, or installed in form of a polyhedral three-dimensional structure, or mounted on a mobile device or a mobile bracket, or mounted on an aerostat platform or an aerostat vehicle. The mobile device or the mobile bracket may include, but be not limited to, a bracket, a light source vector sensor and a movable part, so that the dynamic platform can move to track the sun or increase the output range. The aerostat platform or the aerostat vehicle may be a hot air aerostat platform, such as hot air balloon and a helium vehicle, a mechanical aerostat platform, such as a Dyson sphere and a space elevator, an orbital aerostat platform, such as a satellite and a space station, or a powered aerostat platform, such as a drone.

In the embodiments of the various installing modes described above, it may be further provided with a plurality of light pipes which comprise light receiving ends arranged in intensive array at the output side of at least one optical chamber and terminal ends arranged in communication with the output directions or the light-shielded spaces where light cannot arrive. The light beams output from the respective optical chambers or from a mirror assembly of the optical chambers connected in series can be directed to the light pipes. The light receiving end and the terminal ends are either secured at fixed positions or moveable by being mounted on a mobile member or a movable bracket. The terminal ends of the light pipes may be provided with a special optical device, such as an adjustable reflective mirror, an optical diffuser or a light scatterer, as a means to adjust the output at the terminal ends.

The optical chamber and the operational solar concentrator disclosed herein may have the following applications:

1. Weather Control

The operational solar concentrator herein, when mounted on an aerostat-borne system, is useful for controlling space temperature and air pressure, controlling wind and rain, controlling convection, and promoting water vapor to be carried with the wind, forming clouds and rain in low pressure areas and removing water vapor in high pressure areas, relieving floods and droughts, forest fires, locust plagues, desert and permafrost greening to improve the economic resources of agriculture, forestry, water and land, reducing the greenhouse effect generated by carbon dioxide, and settling dust of air pollution caused by nuclear disasters, volcanoes, meteorites and other disasters into the sea.

When a focal position is in a middle aerial domain, temperature in the middle aerial domain gradually increases, and the ground can still be kept cool. The temperature in the middle aerial domain increases to form a low pressure, and hot air flows upward, which promotes replenishment of nearby cold air, and continuously replenishes and accumulates water vapor. Accumulation of water vapor will promote rainfall, which may be used in desert areas and dry seasons to restore agriculture, forestry ecology and water resources, especially to keep urban areas cool, and to rain in deserts or reservoir catchment areas. Since sunlight needs to travel a long distance to reach the ground, especially for the infrared band of sunlight which has a longer transmission distance, and the focusing effect of the intermediate aerial domain, energy is consumed and converted into heat and kinetic energy to stay in the intermediate aerial domain, so that the ground is maintained at a comfortable and suitable temperature.

On the contrary, when light illumination and temperature of the aerial domain are continuously reduced, high pressure is formed, which can take away water vapor in areas where rainstorm occurs and stop rainfall, thus achieving an effect of controlling the weather.

2. Fire Extinguishment

The operational solar concentrator herein, when mounted on an aerostat-borne system, is useful during the occurrence of a mountain forest fire. The sunlight source in the fire scene can be moved to a safety zone nearby, it is helpful to lowering the fire scene temperature; focusing in the middle aerial domain of peripheral safety zone to form a low pressure, suppressing the convection between the fire scene and the outside to obtain oxygen, the fire scene oxygen concentration is reduced. The generated wide range of low pressure contributes to accelerating the accumulation of water vapor to form clouds and rain, further preventing the fire from spreading and assisting in extinguishment.

3. Reduce Locust Plague

The operational solar concentrator herein, when mounted on an aerostat-borne system, is useful in reducing a locust plague. The locusts tend to take more crops to make up the water loss in high-temperature dry weather, resulting in locust disasters and losses of agricultural and forestry ecological economy. The cooling and rainfall can reduce the excessive feeding of locusts. Secondly, under the phototactic effect of insects, locusts tend to fly towards the focal position in the middle aerial domain, and a part of the pests will be killed by the high temperature at the focal position.

4. Solar Energy Industry

Light and heat can be separately focused, and photovoltaic and photothermal power generation systems can generate electricity at the same time (production capacities of the two power generation systems can be harvested, that is, power generation capacity is twice the conventional power generation systems under a same light-receiving area) and at low costs. The two systems do not interfere with each other, and low attenuation maintains the highest power generation efficiency in the two systems. After the two systems converge light separately, the use area of the photovoltaic module is reduced to improve the power generation efficiency. After the two systems collect heat separately, temperature and power generation efficiency are further improved. Unlike other convergent photovoltaic power generation systems, the invention does not rely on sun tracking system, there reducing the risk of mechanical failure.

Solar energy is initially divided into two types of frequency bands:

43% of infrared frequency band (with a considerable thermal effect, hereinafter referred to as thermal energy); and

57% of visible light and ultraviolet frequency bands (strong energy and no thermal effect, hereinafter referred to as light energy);

The thermal energy and the light energy respectively account for about half of solar energy.

Therefore, the mainstream, conventional solar power generation technology is divided into two categories:

one is photovoltaic power generation, which is only effective for the frequencies of visible light and ultraviolet light; and

the other is photothermal power generation, which is only effective for infrared frequencies.

It means that the existing techniques in the above two fields directly give up nearly half of the energy source before pursuing efficiency.

Conventional ways of integrating power generation systems:

A. superimpose different photovoltaic power generation panels (including quantum well technology); and

B. superimpose thermal power generation system with superimposed photovoltaic panels.

But in fact, in such superimposed systems, many problems will occur as follows:

A. high temperature of thermal energy will reduce power generation efficiency and service life of photovoltaic power generation module;

B. energy obtained by photovoltaic panels in a lower layer is bound to be attenuated by shading; and

C. technologies for integrating photovoltaic panels together are usually costly and, therefore, their popularity is restrained.

In comparison, the invention is advantageous in that:

the operational solar concentrator herein makes light energy and thermal energy focus at two spots separately, so that the two types of power generation systems will not interfere with each other, and no expensive integration technology is needed to build up the invention. Therefore, the invention is capable of increasing power generation capacity at low costs, which is twice of power generation capacity of conventional technologies.

The conventional concentrated photovoltaic power generation systems are advantageous in that: the actual use area of photovoltaic panels is greatly reduced due to adoption of the light concentrating technology, so that photovoltaic power generation technology with relatively high unit price and high efficiency becomes affordable, and when light energy is concentrated, power generation efficiency will be further improved.

Conventional concentrated photovoltaic power generation systems have the following disadvantages:

A. if light energy and heat energy are not separated at first, light concentration would lead to heat accumulation and, as high temperature is the main reason for efficiency decline of photovoltaic panels, some concentrated photovoltaic power generation systems would have to be equipped with heat dissipation plates for active heat dissipation, which consumes more energy and resources;

B. the conventional systems must be installed on a dynamic bracket and used with a sun tracking system to accurately face the sun to generate electricity and if the conventional systems are mistuned slightly, they would fail to generate electricity and malfunction, causing a high risk of mechanical failure and a high cost for maintenance and, thus, lack of popularity; and

C. modules must be installed on a dynamic bracket, resulting in a dilemma of finding a balance between installation density and shading.

The invention is advantageous in that:

A. the light-converging and heat-concentrating techniques used in the invention do not rely on a sun tracking system and, therefore, reduce the risk of mechanical failure and maintenance costs and, in the case of static installation, the invention exhibits the advantages of cost effectiveness and efficiency improvements as a light-convergent photovoltaic power generation device and also the advantage of increased productivity as a light-convergent photothermal power generation device; and

B. in addition to simply supporting power generation, the operational solar concentrator herein can also directly and efficiently support industrial lighting, heating, and air conditioning, which cannot be directly achieved by other solar power generation systems.

5. Other Applications

Long-distance engineering heating, gasification cutting, lighting and detection, indoor convection and heat dissipation, building materials production, building construction, landscape construction, telecommunication, support for steam power or light pressure power energy.

In casting and construction, cheap materials such as sand and gravel can be heated to become molten lava, and then casting formwork and cooling it into high-grade solid igneous rock building material for making molds, building materials, printing or reinforcing buildings.

In transformation of terrain, heavy-duty drilling equipment is not required, the invention is adapted for applying heat to cut into mountains to form tunnels and underground spaces at low costs, and the kerf marks become igneous rock walls after cooling, which can automatically prevent groundwater intrusion (no need to build pumping station any more). The invention is also useful in incinerating and deeply burying waste.

In reconnaissance, defense and search of asteroids, the invention is useful in actively illuminating and searching, changing asteroids' orbits and cutting, melting and plasmaizing asteroids. The costs for launching missiles and rockets can be saved. The invention can provide additional energy and serve as a power source for aerospace activities, mining and navigation and support directional telecommunication.

While the invention has been described with reference to the preferred embodiments above, it should be recognized that the preferred embodiments are given for the purpose of illustration only and are not intended to limit the scope of the present invention and that various modifications and changes, which will be apparent to those skilled in the relevant art, may be made without departing from the spirit and scope of the invention.

What is claimed is:

1. An optical chamber adapted for controlling an output direction of a light beam, and an operational solar concentrator comprising a plurality of the optical chambers, wherein the optical chamber comprises:
a transparent substrate having a first surface and a second surface opposite to the first surface;
a transparent element having a third surface, a fourth surface opposite to the third surface and an edge;
at least one connection element coupled between the transparent element and the transparent substrate, or between the transparent elements, or between the transparent substrates;
wherein the connection element is a movable part and/or a bracket, so that objects connected thereto are either elevated to a fixed position, or arranged to be movable and swingable;
wherein the optical chamber is sealed and encapsulated by the transparent substrate, the transparent element and the connection element, or by the two transparent elements and the connection element, and the optical chamber is configured in a spherical, a polyhedral or an elongated shape, with its interior filled with one or more transparent fluids;
wherein the movable part includes but is limited to an elastic soft film structure, a flexible soft film structure, a telescopic part, a rotary part, a bearing, a slidable part, an electroactive polymer and a combination thereof, which allows the optical chamber to move telescopically, rotationally, swingingly or slidingly along a predetermined direction and allows the optical chamber and especially the transparent element to change their swing direction or curvature, wherein the elastic soft film structure or the flexible soft film structure is provided with an auxiliary motion reservation structure or mounted on the bracket, the auxiliary motion reservation structure being formed by bending or folding the elastic soft film structure or the flexible soft film structure to have a predetermined height, length and motion space, and wherein the telescopic part is selected from the group consisting of a balloon telescopic cell, a folded telescopic cell, and other pneumatic, hydraulic, electrical, mechanical, piezoelectric telescopic parts, and electroactive polymers;
wherein at least one unsealed zone is formed between the connection element and the second surface, between the connection element and the third surface, on the bracket, or between the bracket and the movable part, wherein the unsealed zone is a normally open channel, a normally closed gap or an external port for communicating the optical chambers with one another or with outside when necessary;
wherein the transparent element is an elastic soft film structure or a flexible soft film structure with high ductility, or an electroactive polymer, or a thin plate structure, which is mounted to, or coated on, or adhered to the connection element, and wherein the thin plate structure is a planar thin plate, a thin plate or a lens with a curved surface, or a Fresnel lens with a serrated curved microstructure;
an electronic sensing and execution component mounted inside or outside the optical chamber or installed on another structure, said component may be disposed on the first surface or the second surface of the transparent substrate and on the fourth surface or the third surface of the transparent element, or disposed in the unsealed zone, such as in a normally open channel or a normally closed gap or an external port, the electronic sensing and execution component being preferably transparent, miniaturized or nearly transparent, wherein the electronic sensing and execution component includes, but is not limited, to one or more capacitive electrodes, inductive coils, resistors, photosensitive devices and signal loading devices, electroactive polymers and a combination thereof, and arrange more than one, or staggered, array, (multi-segment) annular, radial, arbitrary, other arrangements, wherein the capacitive electrodes and the inductive coils, through inducing an electric field or generating an electromagnetic force, act to adjust the swing direction and the curved contour of the transparent element or the transparent fluids liquid surface, or the swing direction and the curved contour of liquid level, or further participate in signal loading processing, or switch the unsealed zone from open to closed or vise versa, or further detect the swing direction and curved state of the transparent element, wherein the resistors serve to supply heat to prevent fogging or maintain the temperature to keep the liquid in liquid state, wherein the photosensitive devices, when being arranged in a planar array, are capable of detecting the coordinates and direction of a light beam passing through, or detecting a signal loaded in a source light beam, and wherein the array of the photosensitive devices are adapted for detecting an orientation of the source light beam and arranged to detect light incident from the same direction or divided into several groups for detecting light incident from different directions;
wherein a number of the optical chambers are combined in series or in an array to constitute the operational solar concentrator, wherein the transparent substrates or the transparent elements are arranged in a single layer or in multiple layers, and the connection elements are coupled between the transparent substrates or the transparent elements of the respective layers to either fix and connect them with each other or allow them to be movable and swingable, so that the optical chambers of a same layer and respective layers are arranged according to a predetermined position, amount, size, inclined degree and spacing, or adapted for further movement, adjustment and deformation, and wherein the arrangement may vary and include, but be not limited to, a certain layer of the transparent substrates being of a simple planar structure, a certain layer of the transparent substrates being of a multi-faceted three-dimensional structure or a multi-faceted three-dimensional array, a certain layer of the transparent substrates being divided into a plurality of independent movable sections, a certain layer of the transparent substrates being adapted for moving freely and independently, the outermost transparent substrates serving as upper and lower packaging transparent substrates and constituting a weatherproof package structure to protect the optical chambers disposed therewithin;
wherein the external port is provided with or without a removable high and low pressure external conduit adapted for entry and exit of a liquid into and out of the optical chamber or the intermediate spaces defined by the upper packaging transparent substrates and lower packaging transparent substrates for purposes of temperature and pressure regulation, liquid circulation and substitution, wherein at least one high- or low-pressure pipeline may be disposed inside the bracket or serves as a part of the bracket, or disposed on the connection element, which is either directly connected to the external conduit, or indirectly connected to the external conduit through the external port, so as to perform a fast and low-interference circulation, wherein the high- or low-pressure pipeline is provided with or without at least one micro-hole, micro-tube or valve-equipped flat tube to assist the optical chamber or the telescopic part in regulating the pressure or the telescopic state, wherein the high- or low-pressure pipeline, the micro-hole or the micro-tube is provided with or without a flow control valve which includes but is not limited to a valve-equipped flat tube, a valve plug, an electromagnetic mechanical flow control valve and an electroactive polymer, wherein the valve-equipped flat tube or the valve plug is further provided with or without a capacitive electrode or an inductive coil, so that the valve-equipped flat tube or the valve plug is converted to an operational flow control valve like an electromagnetic mechanical flow control valve, which is adapted to switch on and off states by inducing an electric field or a magnetic field, and the respective telescopic parts are connected to the high and low pressure conduit through two of the flow control valves to perform telescopic control;
wherein the first surface or the fourth surface of the optical chamber is coated with or without an optical film to become a special optical device, and the optical film includes but is not limited to a filter film, a semi-transparent film, a reflective film and a multi-energy level film, or the special optical device adopts a conventional reflector or other optical device which includes but is not limited to a planar mirror, a concave mirror and a convex mirror;
wherein the operational solar concentrator is adapted to, according to a command, change orientations of light beams output from the respective optical chambers among multiple application positions by using various items and devices in a wide application space, so as to generate one or more converged light beams, and adapted to adjust an amount of the converged light beams and an intensity of converged light energy, wherein the converged light beams are modified or not modified into a directional light beam through the optical chambers, wherein when the system is equipped with or without a camera and a computer vision technical module or connected with a data link, the converged light beam or the directional light beam is adapted for tracking and directing the light beam towards a moveable target and can be applied in cutting large objects, such as cutting rocks, buildings, tunnels and underground spaces, transforming terrain, or heating cheap materials such as heating sand and gravel into molten lava, pouring into formwork and then cooling it to realize casting, construction, and three-dimensional printing and the system also supports directional beam communication, light beam probing and light beam energy transmission, and wherein when the system is provided with a reflective film, the converged light beam or the directional light beam can be projected at a wider range to support various aerospace activities.

2. The operational solar concentrator as claimed in claim 1, whose entire mechanical architecture and system are realized by a bio-architecture and system, which involves application of biotechnology, genetic engineering and cell technology, with reference to the architecture of the operational solar concentrator and the operation mechanism of chameleon epidermal cells, thereby producing the operational solar concentrator comprising artificial cell and tissue planar arrays, which are attached on the transparent substrate or within a weatherproof package, and wherein small channels and apertures are formed, through which a nutrient solution or a culture medium may be transmitted or sprayed;
wherein at least optical chamber cells or eyeball crystal-like and ciliary muscle-like structures are arranged on the artificial cell and tissue planar arrays and controlled by electrodes, electronic signal wiring or nerve cells so that the respective optical chamber cells or the respective eyeball crystals can be deformed in a controlled manner and enabled to output light individually or converging a light beam cooperatively;
wherein vascular bundle cells or blood circulation system are disposed or not disposed for mass transfer and temperature control;
wherein photosynthetic cells or pigment cells disposed on the outermost layer or disposed in proportion to the optical chamber cells to provide operational energy source so that the light-receiving areas and deformation degrees of the respective cells, as well as the light transmittance or the output direction of the reflected light, are adapted for controlled adjustment.

3. The optical chamber adapted for controlling an output direction of a light beam as claimed in claim 1, or an operational solar concentrator comprising a plurality of the optical chambers, or a weatherproof packaging structure comprising the optical chambers, which is installed by the following modes: directly mounted on, replacing, or constitutes a roof, or mounted on a relatively high static position, or installed in form of a polyhedral three-dimensional structure, or mounted on a mobile device or a mobile bracket, or mounted on an aerostat platform or an aerostat vehicle, wherein the mobile device or the mobile bracket includes, but is not limited to, a bracket, a light source vector sensor and a movable part, so that the dynamic platform can move to track the sun or increase the output range, wherein the aerostat platform or the aerostat vehicle is a hot air aerostat platform, such as hot air balloon and a helium vehicle and a platform thereof, a mechanical aerostat platform, such as a Dyson sphere and a space elevator, an orbital aerostat platform, such as a satellite and a space station, or a powered aerostat platform, such as a drone.

4. The optical chamber adapted for controlling an output direction of a light beam as claimed in claim 2, or an operational solar concentrator comprising a plurality of the optical chambers, or a weatherproof packaging structure comprising the optical chambers, which is installed by the following modes: directly mounted on, replacing, or constitutes a roof, or mounted on a relatively high static position, or installed in form of a polyhedral three-dimensional structure, or mounted on a mobile device or a mobile bracket, or mounted on an aerostat platform or an aerostat vehicle, wherein the mobile device or the mobile bracket includes, but is not limited to, a bracket, a light source vector sensor and a movable part, so that the dynamic platform can move to track the sun or increase the output range, wherein the aerostat platform or the aerostat vehicle is a hot air aerostat platform, such as hot air balloon and a helium vehicle, a mechanical aerostat platform, such as a Dyson sphere and a space elevator, an orbital aerostat platform, such as a satellite and a space station, or a powered aerostat platform, such as a drone.

5. Any one of the installation modes as claimed in claimed 3, further comprising a plurality of light pipes which comprise light receiving ends arranged in intensive array at the output side of at least one optical chamber and terminal ends arranged in communication with the output directions or the light-shielded spaces where light cannot arrive, wherein the light beams output from the respective optical chambers or from a mirror assembly of the optical chambers connected in series are directed to the light pipes;
wherein the light receiving end and the terminal ends are either secured at fixed positions or moveable by being mounted on a mobile member or a movable bracket;
wherein the terminal ends of the light pipes are provided with or without a special optical device, such as an adjustable reflective mirror, an optical diffuser or a light scatterer, as a means to adjust the output at the terminal ends.

6. Any one of the installation modes as claimed in claimed 4, further comprising a plurality of light pipes which comprise light receiving ends arranged in intensive array at the output side of at least one optical chamber and terminal ends arranged in communication with the output directions or the light-shielded spaces where light cannot arrive, wherein the light beams output from the respective optical chambers or from a mirror assembly of the optical chambers connected in series are directed to the light pipes;
wherein the light receiving end and the terminal ends are either secured at fixed positions or moveable by being mounted on a mobile member or a movable bracket;
wherein the terminal ends of the light pipes are provided with or without a special optical device, such as an adjustable reflective mirror, an optical diffuser or a light scatterer, as a means to adjust the output at the terminal ends.
